(19) United States
(12) Patent Application Publication
(10) Pub. No.: US 2005/0271108 A1
(43) Pub. Date: Dec. 8, 2005

(54) Semiconductor laser device

(75) Inventors: Kazuhiko Wada, Mihara-shi (JP); Keisuke Miyazaki, Yamatokoriyama-shi (JP); Taiji Morimoto, Nara-shi (JP); Masaki Tatsumi, Mihara-shi (JP); Yoshiaki Ueda, Tenri-shi (JP)

Correspondence Address: Barry E. Bretschneider;Morrison & Foerster LLP, Suite 300, 1650 Tysons Boulevard, McLean, VA, 22102, US

(73) Assignee: Sharp Kabushiki Kaisha, Osaka-shi (JP)

(21) Appl. No.: 11/138,382

(22) Filed: May 27, 2005

(30) Foreign Application Priority Data
Jun. 2, 2004 (JP) 2004-164619

(51) Int. Cl. H01S 5/00

(52) U.S. Cl. 372/50.12; 372/50.1

(57) ABSTRACT

A manufacturing method for a semiconductor laser in which a ratio of a layer thickness obtained by adding the layer thickness of a p-type GaAs cap layer and the layer thickness of a p-type AlₓGa₁₋ₓAs (X=0.550) second cladding layer to a layer thickness obtained by adding the layer thickness of a p-type GaAs cap layer and the layer thickness of a p-type AlGaInP second upper cladding layer is identical to a ratio of an etching rate for dry etching of the p-type GaAs cap layer and the p-type AlₓGa₁₋ₓAs (X=0.550) second cladding layer to an etching rate for dry etching of the p-type GaAs cap layer and the p-type AlGaInP second upper cladding layer.

### CROSS-REFERENCE TO RELATED APPLICATIONS

This nonprovisional application claims priority under 35 U.S.C. §119(a) on Patent Application No. 2004-164619 filed in Japan on 02 Jun. 2004, the entire contents of which are incorporated herein by reference.

### BACKGROUND OF THE INVENTION

The present invention relates to a semiconductor laser device in which a plurality of laser emitting sections for emitting laser beams with different wavelengths are formed on a single substrate, and to a manufacturing method therefor.

There have conventionally been drive apparatuses capable of optically recording/reproducing information on both DVDs (Digital Versatile Disc) and CDs (Compact Discs). Optical pickup units for such drive apparatuses have a 650 nm-band red laser device for supporting the DVDs and a 780 nm-band infrared laser device for supporting the CDs.

However, the optical pickup units incorporate the red laser device and the infrared laser device as one package. This causes a disadvantage of difficulty in downsizing and cost reduction. A monolithic-type double wavelength laser device has been proposed as a semiconductor laser device capable of solving such a disadvantage as the above. The monolithic-type double wavelength laser device emits 650 nm-band red laser light and 780 nm-band infrared laser light. Particularly, in the monolithic-type double wavelength laser device, the red laser emitting section and the infrared laser emitting section are formed on one substrate.

FIG. 3 is a schematic cross sectional view showing a conventional monolithic-type double wavelength laser device.

The monolithic-type double wavelength laser device is made up of an n-type GaAs substrate 101, an n-type GaAs buffer layer 102 formed on the n-type GaAs substrate 101, and first and second laser emitting sections L101, L102 formed on the n-type GaAs buffer layer 102. A p-side AuZn/Au 114A is formed on the first laser emitting section L101 while a p-side AuZn/Au 114B is formed on the second laser emitting section L102. Moreover, an n-side AuGe/Ni electrode 115 is formed under the n-type GaAs substrate 101.

The first laser emitting section L101 is composed of an n-type AlGaAs cladding layer 103, an AlGaAs multiple quantum well active layer 104 with oscillation wavelength of 780 nm, a p-type AlGaAs cladding layer 105, a p-type GaAs cap layer 106 and n-type GaAs current narrowing layers 113A, 113B. Moreover, the upper portion of the p-type AlGaAs cladding layer 105 and the entire portion of the p-type GaAs cap layer 106 constitute a first ridge stripe. An n-type GaAs current narrowing layer 113 is formed so as to sandwich the first ridge stripe from both the sides thereof.

The second laser emitting section L102 is composed of an n-type InGaP buffer layer 108, an n-type AlGaInP cladding layer 109, a multiple quantum well active layer 110 with oscillation wavelength of 650 nm, a p-type AlGaInP cladding layer 111, a p-type GaAs cap layer 112 and n-type GaAs current narrowing layers 113C, 114D. Moreover the upper portion of the p-type AlGaInP cladding layer 111 and the entire portion of the p-type GaAs cap layer 112 constitute a second ridge stripe. The n-type GaAs current narrowing layers 113C, 114D are formed so as to sandwich the second ridge stripe from both the sides thereof.

The monolithic-type double wavelength laser device is formed as shown below.

First, as shown in FIG. 4A, an n-type GaAs buffer layer 102, an n-type AlGaAs cladding layer 103′, a multiple quantum well active layer 104′, a p-type AlGaAs cladding layer 105′ and a p-type GaAs cap layer 106′ are laminated in sequence on an n-type GaAs substrate 101.

Next, after a resist film was formed on a region where the first laser emitting section L101 should be formed, wet etching such as sulfuric acid non-selective etching and HF-base AlGaAs selective etching are performed to remove parts of the n-type AlGaAs cladding layer 103′, the multiple quantum well active layer 104′, the p-type AlGaAs cladding layer 105′ and the p-type GaAs cap layer 106′. Consequently, as shown in FIG. 4B, an n-type AlGaAs cladding layer 103, a multiple quantum well active layer 104, an p-type AlGaAs cladding layer 105″ and a p-type GaAs cap layer 106″ are obtained.

Next, as shown in FIG. 4C, an n-type InGaP buffer layer 108′, an n-type AlGaInP cladding layer 109′, a multiple quantum well active layer 110′, an p-type AlGaInP cladding layer 111′ and a p-type GaAs cap layer 112′ are laminated in sequence on both of the n-type GaAs buffer layer 102 and the p-type GaAs cap layer 106″.

Next, after a resist film is formed on a region where the second laser emitting section L102 should be formed, the n-type InGaP buffer layer 108′, the n-type AlGaInP cladding layer 109′, the multiple quantum well active layer 110′, the p-type AlGaInP cladding layer 111′ and the p-type GaAs cap layer 112′ are partially wet-etched. Consequently, as shown in FIG. 4D, an n-type InGaP buffer layer 108, an n-type AlGaInP cladding layer 109, a multiple quantum well active layer 110, a p-type AlGaInP cladding layer 111″ and a p-type GaAs cap layer 112″ are obtained.

Next, the p-type AlGaAs cladding layer 105″ and the p-type GaAs cap layer 106″ are partially wet-etched to form a first ridge stripe, while the p-type AlGaInP cladding layer 111″ and the p-type GaAs cap layer 112″ are partially wet-etched to form a second ridge stripe. More particularly, as shown in FIG. 4E, a p-type AlGaAs cladding layer 105, a p-type GaAs cap layer 106, a p-type AlGaInP cladding layer 111 and a p-type GaAs cap layer 112 are formed. Then, an n-type GaAs current narrowing layer 113 is laminated on the entire surface of the wafer.

Next, the n-type GaAs current narrowing layer 113 is partially wet-etched to form, as shown in FIG. 4F, n-type GaAs current narrowing layers 113A, 113B, 113C and 113D, by which first and second laser emitting sections L101, L102 are obtained. Then, p-side AuZn/Au 114A, 114B are formed on the first and second laser emitting sections L101, L102 while an n-side AuGe/Ni electrode 115 is formed under the n-type GaAs substrate 101.

Thus-produced monolithic-type double wavelength laser device emits 780 nm-band infrared laser light from the first laser emitting section L101 and 650 nm-band red laser light from the second laser emitting section L102, which allows downsizing and cost reduction of the optical pickup unit.

However, the conventional manufacturing method for the monolithic-type double wavelength laser device has following disadvantages.

Since the first ridge stripe contains an AlGaAs-base material and the second ridge stripe contains an AlGaInP-base material, specified regions should be covered with a resist film when forming the first and second ridge stripes only through wet etching. Specifically, in the case of forming the first ridge stripe, the region for forming the second laser emitting section L102 should be covered with a resist film, while in the case of forming the second ridge stripe the region for forming the first laser emitting section L101 should be covered with another resist film. Therefore, in order to form the first and second ridge stripes, etching masks of at least two kinds are required. As a result, forming the first and second ridge stripes requires at least two photolithography operations, thereby causing such a disadvantage that the manufacturing steps are complicated.

Moreover, the photolithography operation for forming the first ridge stripe and the photolithography operation for forming the second ridge stripe are separately performed, and therefore, errors of a luminous point interval between laser light beams are increased. More particularly, it is disadvantageously impossible to set the luminous point positions of the first laser emitting section L101 and the second laser emitting section L102 with high precision.

This monolithic-type double wavelength laser device is disclosed, for example, in JP 2000-244060 A.

To solve the above disadvantage, it is conceivable to employ the method in which the first and second ridge stripes are formed by using the etching masks of one kind. In the case of using this method, although the first and second ridge stripes need to be formed in combination of dry etching having no selectivity of materials and wet etching having selectivity of materials, the dry etching may cause over etching. This results in deformation of the first ridge stripe or the second ridge stripe. Thus, due to occurrence of the over etching during the dry etching, it is impossible to form the first and second ridge stripes by the etching masks of one kind.

### SUMMARY OF THE INVENTION

An object of the present invention is to provide a semiconductor laser device capable of simplifying the manufacturing process and setting the position of luminous points of the first and second laser emitting sections with high precision and to provide a manufacturing method therefor.

In order to achieve the above-mentioned object, a first aspect of the present invention provides a semiconductor laser device, comprising:
a substrate;
a first laser emitting section formed on the substrate for emitting a laser light beam with a first wavelength; and
a second laser emitting section formed on the substrate for emitting a laser light beam with a second wavelength different from the first wavelength,
the first laser emitting section having a first conductivity-type lower cladding layer, an active layer, a second conductivity-type first upper cladding layer, an etching stop layer, a second conductivity-type second upper cladding layer and a second conductivity-type cap layer,
the second laser emitting section having a first conductivity-type lower cladding layer, an active layer, a second conductivity-type first upper cladding layer, an etching stop layer, a second conductivity-type second upper cladding layer and a second conductivity-type cap layer, wherein
a first ridge stripe is comprised of the second conductivity-type second upper cladding layer and the second conductivity-type cap layer of the first laser emitting section, while a second ridge stripe is comprised of the second conductivity-type second upper cladding layer and the second conductivity-type cap layer of the second laser emitting section, and wherein
a ratio of a layer thickness obtained by adding a layer thickness of the second conductivity-type cap layer of the first laser emitting section and a layer thickness of the second conductivity-type second upper cladding layer of the first laser emitting section to a layer thickness obtained by adding a layer thickness of the second conductivity-type cap layer of the second laser emitting section and a layer thickness of the second conductivity-type second upper cladding layer of the second laser emitting section is almost identical to a ratio of an etching rate for etching the second conductivity-type second upper cladding layer of the first laser emitting section and the second conductivity-type cap layer of the first laser emitting section to an etching rate for etching the second conductivity-type second upper cladding layer of the second laser emitting section and the second conductivity-type cap layer of the second laser emitting section.

In the present specification, the phrase “almost identical” refers to the condition that in comparison of two numerical values for example, one value is within the range of 90% to 110% of the other value.

According to the semiconductor laser device, a ratio of a layer thickness obtained by adding a layer thickness of the second conductivity-type cap layer of the first laser emitting section and a layer thickness of the second conductivity-type second upper cladding layer of the first laser emitting section to a layer thickness obtained by adding a layer thickness of the second conductivity-type cap layer of the second laser emitting section and a layer thickness of the second conductivity-type second upper cladding layer of the second laser emitting section is almost identical to a ratio of an etching rate for etching the second conductivity-type second upper cladding layer of the first laser emitting section and the second conductivity-type cap layer of the first laser emitting section to an etching rate for etching the second conductivity-type second upper cladding layer of the second laser emitting section and the second conductivity-type cap layer of the second laser emitting section. Consequently, in the case where dry etching is simultaneously performed on the layers to be the second conductivity-type second cladding layer and the second conductivity-type cap layer of the first laser emitting section and on the layers to be second conductivity-type second upper cladding layer and the second conductivity-type cap layer of the second laser emitting section, the residual thickness of both the layers becomes almost identical.

Therefore, even when dry etching is performed to form the second conductivity-type second upper cladding layers and the second conductivity-type cap layers of the first and second laser emitting sections, it is possible to easily prevent over etching from occurring during the dry etching. As a result, with use of the etching masks of one kind, it is possible to form the second conductivity-type second upper cladding layer and the second conductivity-type cap layer of the first laser emitting section and the second conductivity-type second upper cladding layer and the second conductivity-type cap layer of the second laser emitting section. In other words, the first and second ridge stripes are formed by the etching masks of one kind. Thus, only one photolithography operation is necessary for forming the first and second ridge stripes, thereby allowing the manufacturing step to be simplified.

Moreover, by forming the first and second ridge stripes with the etching masks of one kind, the position of luminous points of the first and second laser emitting sections may be set with higher precision than by forming the first and second ridge stripes with the etching masks of two kinds.

The layer thickness in the first and second laser emitting sections should preferably be adjusted by the second conductivity-type cap layer which exerts less influence on the characteristics of laser.

In one embodiment of the present invention, the first laser emitting section contains an AlGaAs-base material while the second laser emitting section contains an AlGaInP-base material.

In one embodiment of the present invention, the first ridge stripe extends along a resonator direction of the laser light beam with the first wavelength, while the second ridge stripe extends along a resonator of the laser light beam with the second wavelength.

A second aspect of the present invention provides a manufacturing method for a semiconductor laser device having a substrate; a first laser emitting section formed on the substrate for emitting a laser light beam with a first wavelength; and a second laser emitting section formed on the substrate for emitting a laser light beam with a second wavelength different from the first wavelength,
the first laser emitting section having a first conductivity-type lower cladding layer, an active layer, a second conductivity-type first upper cladding layer, an etching stop layer, a second conductivity-type second upper cladding layer and a second conductivity-type cap layer,
the second laser emitting section having a first conductivity-type lower cladding layer, an active layer, a second conductivity-type first upper cladding layer, an etching stop layer, a second conductivity-type second upper cladding layer and a second conductivity-type cap layer, wherein
a first ridge stripe is comprised of the second conductivity-type second upper cladding layer of the first laser emitting section and the second conductivity-type cap layer of the first laser emitting section, while a second ridge stripe is comprised of the second conductivity-type second upper cladding layer of the second laser emitting section and the second conductivity-type cap layer of the second laser emitting section, the manufacturing method comprising the steps of:
forming a first semiconductor layer to be the second conductivity-type second upper cladding layer of the first laser emitting section on the substrate;
forming a second semiconductor layer to be the second conductivity-type cap layer of the first laser emitting section on the first semiconductor layer;
forming a third semiconductor layer to be the second conductivity-type second upper cladding layer of the second laser emitting section on the substrate;
forming a fourth semiconductor layer to be the second conductivity-type cap layer of the second laser emitting section on the third semiconductor layer;
forming an etching mask on the second semiconductor layer and the fourth semiconductor layer in one photolithography operation; and
performing etching with use of the etching mask so as to remove parts of the first semiconductor layer, the second semiconductor layer, the third semiconductor layer and the fourth semiconductor layer, wherein
a ratio of a layer thickness obtained by adding a layer thickness of the second semiconductor layer and a layer thickness of the first semiconductor layer to a layer thickness obtained by adding a layer thickness of the fourth semiconductor layer and a layer thickness of the third semiconductor layer is almost identical to a ratio of an etching rate for etching from the second semiconductor layer toward the substrate to the first semiconductor layer to an etching rate for etching from the fourth semiconductor layer toward the substrate to the third semiconductor layer.

According to the manufacturing method for the semiconductor laser device, as stated above, a ratio of a layer thickness obtained by adding a layer thickness of the second semiconductor layer and a layer thickness of the first semiconductor layer to a layer thickness obtained by adding a layer thickness of the fourth semiconductor layer and a layer thickness of the third semiconductor layer is almost identical to a ratio of an etching rate for etching from the second semiconductor layer toward the substrate to the first semiconductor layer to an etching rate for etching from the fourth semiconductor layer toward the substrate to the third semiconductor layer. Consequently, when dry etching is simultaneously performed on the second semiconductor layer and the fourth semiconductor layer, and dry etching is performed from the second and fourth semiconductor layers toward the substrate to the mid point of the first and third semiconductor layers, the residual thickness of the first semiconductor layer becomes almost identical to the residual thickness of the third semiconductor layer. Then, when the residual portions of the first and third semiconductor layers are wet-etched, the second conductivity-type second upper cladding layers and the second conductivity-type cap layers of the first and second laser emitting sections are obtained.

Therefore, even when dry etching is employed to form the second conductivity-type second upper cladding layers and the second conductivity-type cap layers of the first and second laser emitting sections, it is possible to easily prevent over etching from occurring during the dry etching. As a result, the second conductivity-type second upper cladding layer and the second conductivity-type cap layer of the first laser emitting section and the second conductivity-type second upper cladding layer and the second conductivity-type cap layer of the second laser emitting section may be formed by the etching masks of one kind. In other words, the first and second ridge stripes are formed by the etching masks of one kind. Thus, only one photolithography operation is necessary for forming the first and second ridge stripes, thereby allowing the manufacturing step to be simplified.

Moreover, by forming the first and second ridge stripes by the etching masks of one kind, the position of luminous points of the first and second laser emitting sections may be set with higher precision than by forming the first and second ridge stripes by the etching masks of two kinds.

Moreover, in the case where the first ridge stripe contains AlGaAs and the second ridge stripe contains AlGaInP, it is preferable to perform wet etching for forming the first ridge stripe with use of fluorinated acid having a sufficiently small etching rate for AlGaInP as an etchant. Also, it is preferable to perform wet etching for forming the second ridge stripe with use of phosphoric acid having a sufficiently small etching rate for AlGaAs as an etchant.

In one embodiment of the present invention, the etching mask is formed from one photomask.

In one embodiment of the present invention, etching with use of the etching mask is performed in combination of dry etching and wet etching performed after the dry etching.

In one embodiment of the present invention, in the wet etching, an etchant allowing selective etching of the first semiconductor layer is used and an etchant allowing selective etching of the third semiconductor layer is used.

In the semiconductor laser device according to the first aspect of the invention, as mentioned above, a ratio of a layer thickness obtained by adding a layer thickness of the second conductivity-type cap layer of the first laser emitting section and a layer thickness of the second conductivity-type second upper cladding layer of the first laser emitting section to a layer thickness obtained by adding a layer thickness of the second conductivity-type cap layer of the second laser emitting section and a layer thickness of the second conductivity-type second upper cladding layer of the second laser emitting section is almost identical to a ratio of an etching rate for etching the second conductivity-type second upper cladding layer and the second conductivity-type cap layer of the first laser emitting section to an etching rate for etching the second conductivity-type second upper cladding layer and the second conductivity-type cap layer of the second laser emitting section. Consequently, the residual thickness of both the layers becomes almost identical in the case where dry etching is simultaneously performed on the layers to be the second conductivity-type second cladding layer and the second conductivity-type cap layer of the first laser emitting section and on the layers to be second conductivity-type second upper cladding layer and the second conductivity-type cap layer of the second laser emitting section.

Therefore, it is possible to easily prevent over etching from occurring when dry etching is performed to form the second conductivity-type second upper cladding layers and the second conductivity-type cap layers of the first and second laser emitting sections. As a result, with use of the etching masks of one kind, it is possible to form the second conductivity-type second upper cladding layers and the second conductivity-type cap layers of the first and second laser emitting sections. In other words, the first and second ridge stripes are formed by the etching masks of one kind. Thus, only one photolithography operation is necessary for forming the first and second ridge stripes, thereby allowing the manufacturing step to be simplified.

Moreover, by forming the first and second ridge stripes with use of the etching masks of one kind, the position of luminous points of the first and second laser emitting sections may be set with higher precision than by forming the first and second ridge stripes with use of the etching masks of two kinds.

In the semiconductor laser device according to the second aspect of the present invention, as stated above, a ratio of a layer thickness obtained by adding a layer thickness of the second semiconductor layer and a layer thickness of the first semiconductor layer to a layer thickness obtained by adding a layer thickness of the fourth semiconductor layer and a layer thickness of the third semiconductor layer is almost identical to a ratio of an etching rate for etching from the second semiconductor layer toward the substrate to the first semiconductor layer to an etching rate for etching from the fourth semiconductor layer toward the substrate to the third semiconductor layer. Consequently, when dry etching is simultaneously performed on the second semiconductor layer and the fourth semiconductor layer, and dry etching is performed from the second and fourth semiconductor layers toward the substrate to the mid point of the first and third semiconductor layers, the residual thickness of the first semiconductor layer and the residual thickness of the third semiconductor layer become almost identical. Then, when the residual portions of the first and third semiconductor layers are wet-etched, the second conductivity-type second upper cladding layers and the second conductivity-type cap layers of the first and second laser emitting sections are obtained.

Therefore, since the second conductivity-type second upper cladding layers and the second conductivity-type cap layers of the first and second laser emitting sections are formed from the first semiconductor layer, the second semiconductor layer, the third semiconductor layer and the fourth semiconductor layer, it is possible to easily prevent over etching from occurring even when dry etching is employed. As a result, with use of the etching masks of one kind, it is possible to form the second conductivity-type second upper cladding layers and the second conductivity-type cap layers of the first and second laser emitting sections. In other words, the first and second ridge stripes are formed by the etching masks of one kind. Thus, only one photolithography operation is necessary for forming the first and second ridge stripes, thereby allowing the manufacturing step to be simplified.

Moreover, by forming the first and second ridge stripes with use of the etching masks of one kind, the position of luminous points of the first and second laser emitting sections are set with higher precision than by forming the first and second ridge stripes with use of the etching masks of two kinds.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic cross sectional view showing a monolithic-type double wavelength laser device in one embodiment of the present invention;

FIG. 2A is a schematic cross sectional view showing a manufacturing step of the monolithic-type double wavelength laser device;

FIG. 2B is a schematic cross sectional view showing a manufacturing step of the monolithic-type double wavelength laser device;

FIG. 2C is a schematic cross sectional view showing a manufacturing step of the monolithic-type double wavelength laser device;

FIG. 2D is a schematic cross sectional view showing a manufacturing step of the monolithic-type double wavelength laser device;

FIG. 2E is a schematic cross sectional view showing a manufacturing step of the monolithic-type double wavelength laser device;

FIG. 2F is a schematic cross sectional view showing a manufacturing step of the monolithic-type double wavelength laser device;

FIG. 2G is a schematic cross sectional view showing a manufacturing step of the monolithic-type double wavelength laser device;

FIG. 2H is a schematic cross sectional view showing a manufacturing step of the monolithic-type double wavelength laser device;

FIG. 2I is a schematic cross sectional view showing a manufacturing step of the monolithic-type double wavelength laser device;

FIG. 2J is a schematic cross sectional view showing a manufacturing step of the monolithic-type double wavelength laser device;

FIG. 2K is a schematic cross sectional view showing a manufacturing step of the monolithic-type double wavelength laser device;

FIG. 2L is a schematic cross sectional view-showing a manufacturing step of the monolithic-type double wavelength laser device;

FIG. 3 is a schematic cross sectional view showing a conventional monolithic-type double wavelength laser device;

FIG. 4A is a schematic cross sectional view showing a manufacturing step of the conventional monolithic-type double wavelength laser device;

FIG. 4B is a schematic cross sectional view showing a manufacturing step of the conventional monolithic-type double wavelength laser device;

FIG. 4C is a schematic cross sectional view showing a manufacturing step of the conventional monolithic-type double wavelength laser device;

FIG. 4D is a schematic cross sectional view showing a manufacturing step of the conventional monolithic-type double wavelength laser device;

FIG. 4E is a schematic cross sectional view showing a manufacturing step of the conventional monolithic-type double wavelength laser device; and

FIG. 4F is a schematic cross sectional view showing a manufacturing step of the conventional monolithic-type double wavelength laser device.

### DETAILED DESCRIPTION OF THE INVENTION

The Present invention will be described in detailed below based on embodiments thereof.

FIG. 1 is a schematic cross sectional view showing a monolithic-type double wavelength laser device in one embodiment of the present invention.

The monolithic-type double wavelength laser device is made up of an n-type GaAs substrate 1, an n-type GaAs buffer layer 2 formed on the n-type GaAs substrate 1, and first and second laser emitting sections L1, L2 formed on the n-type GaAs buffer layer 2. A p-side AuZn/Au 14A is formed on the first laser emitting section L1 while a p-side AuZn/Au 14B is formed on the second laser emitting section L2. Moreover, an n-side AuGe/Ni electrode 15 is formed under the n-type GaAs substrate 1.

The first laser emitting section L1 contains an AlGaAs-base material and emits infrared laser light. Specifically, the first laser emitting section LI is composed of an n-type AlGaAs cladding layer 3, an n-type AlₓGa₁₋ₓAs (X=0.485) first lower cladding layer 16, an n-type AlₓGa₁₋ₓAs (X=0.550) second lower cladding layer 17, an AlGaAs multiple quantum well active layer 4 with oscillation wavelength of 780 nm, a p-type AlₓGa₁₋ₓAs (X=0.550) first upper cladding layer 18, a p-type GaAs etching stop layer 19, a p-type AlₓGa₁₋ₓAs (X=0.550) second cladding layer 20, a p-type GaAs cap layer 6 and n-type GaAs current narrowing layers 13A, 13B Moreover, the p-type AlₓGa₁₋ₓAs (X=0.550) second cladding layer 20 and the p-type GaAs cap layer 6 constitute a first ridge stripe. An n-type GaAs current narrowing layer 13 is formed so as to sandwich the first ridge stripe from both the sides.

The second laser emitting section L2 contains an AlGaInP-base material and emits red laser light. Specifically, the second laser emitting section L2 is composed of an n-type GaAs buffer layer 7, an n-type InGaP buffer layer 8, an n-type AlGaInP lower cladding layer 9, an AlGaInP multiple quantum well active layer 10 with oscillation wavelength of 650 nm, a p-type AlGaInP first upper cladding layer 21, a p-type InGaP etching stop layer 22, a p-type AlGaInP second upper cladding layer 23, a p-type GaAs cap layer 12 and n-type GaAs current narrowing layers 13C, 14D. Moreover, the p-type AlGaInP second upper cladding layer 23 and the p-type GaAs cap layer 12 constitute a second ridge stripe. The n-type GaAs current narrowing layers 13C, 14D are formed so as to sandwich the second ridge stripe from both sides thereof.

According to the monolithic-type double wavelength laser device, a ratio of a layer thickness obtained by adding the layer thickness of the p-type GaAs cap layer 6 and the layer thickness of the p-type AlₓGa₁₋ₓAs (X=0.550) second cladding layer 20 to a layer thickness obtained by adding the layer thickness of p-type GaAs cap layer 12 and the layer thickness of the p-type AlGaInP second upper cladding layer 23 is identical to a ratio of an etching rate for dry etching of the p-type GaAs cap layer 6 and the p-type AlₓGa₁₋ₓAs (X-=0.550) second cladding layer 20 to an etching rate for dry etching of the p-type GaAs cap layer 12 and the p-type AlGaInP second upper cladding layer 23. Consequently, in the case where dry etching is simultaneously performed on the layers to be the p-type GaAs cap layer 6 and the p-type AlₓGa₁₋ₓAs (X=0.550) second cladding layer 20 and on the layers to be the p-type GaAs cap layer 12 and the p-type AlGaInP second upper cladding layer 23, the residual thickness of both the layers becomes almost identical.

Therefore, even when dry etching is performed to form the p-type GaAs cap layer 6, the p-type AlₓGa₁₋ₓAs (X=0.550) second cladding layer 20, the p-type GaAs cap layer 12 and the p-type AlGaInP second upper cladding layer 23, it is possible to easily prevent over etching from occurring during the dry etching. As a result, the p-type GaAs cap layer 6, the p-type AlₓGa₁₋ₓAs (X=0.550) second cladding layer 20, the p-type GaAs cap layer 12 and the p-type AlGaInP second upper cladding layer 23 may be formed by etching masks of one kind. In other words, the first and second ridge stripes are formed by the etching masks of one kind. Thus, only one photolithography operation is necessary for forming the first and second ridge stripes, thereby allowing the manufacturing step to be simplified.

Moreover, by forming the first and second ridge stripes by the etching masks of one kind, the position of luminous points of the first and second laser emitting sections may be set with higher precision than by forming the first and second ridge stripes by the etching masks of two kinds.

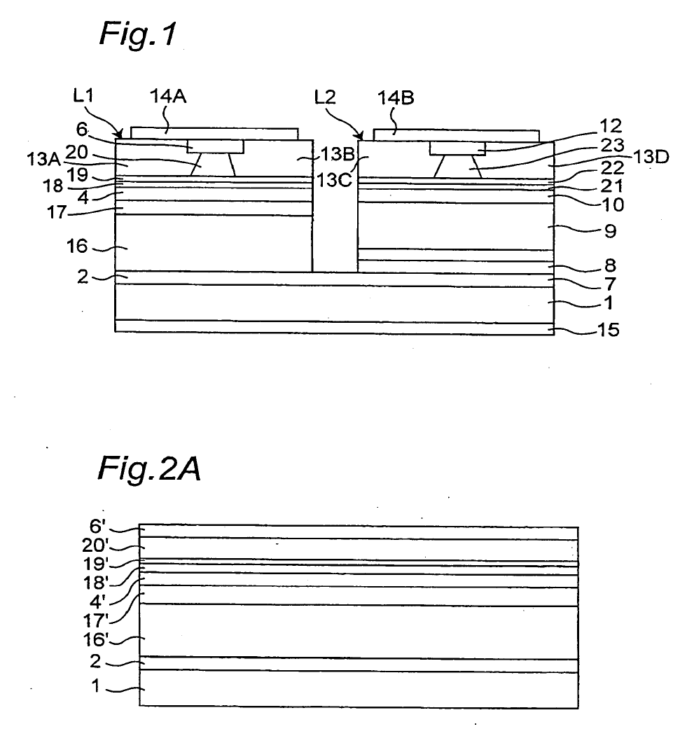

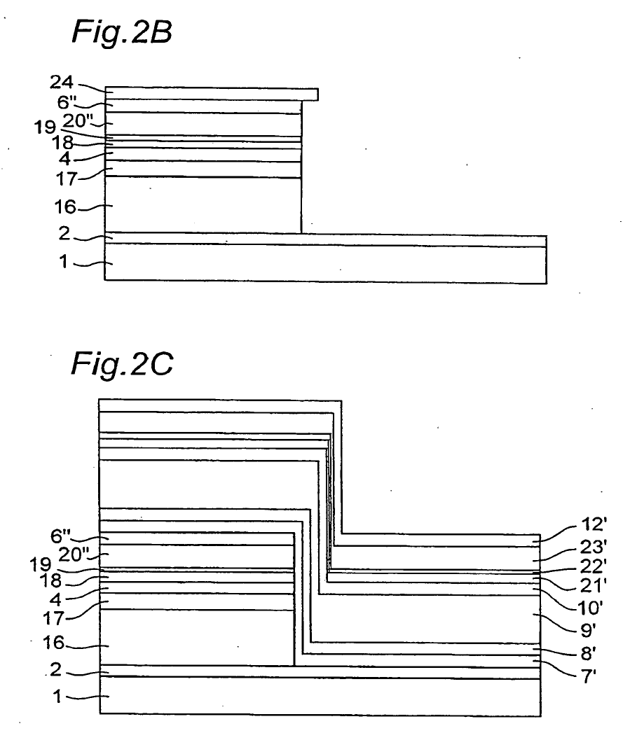

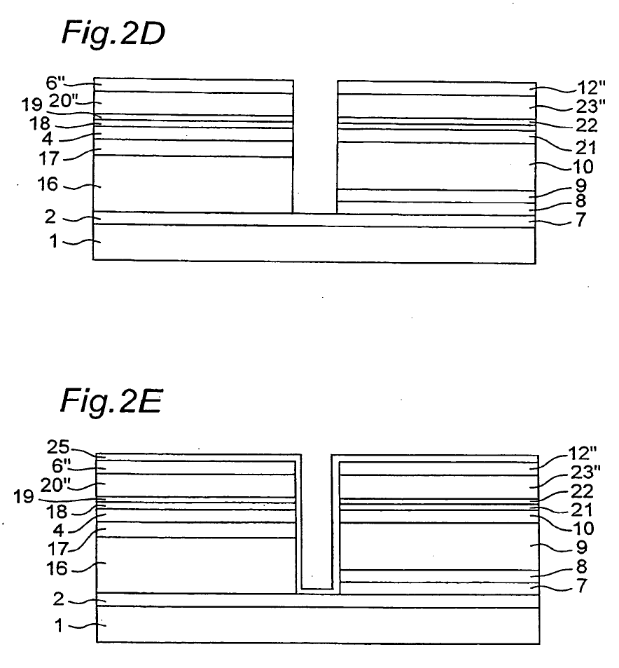

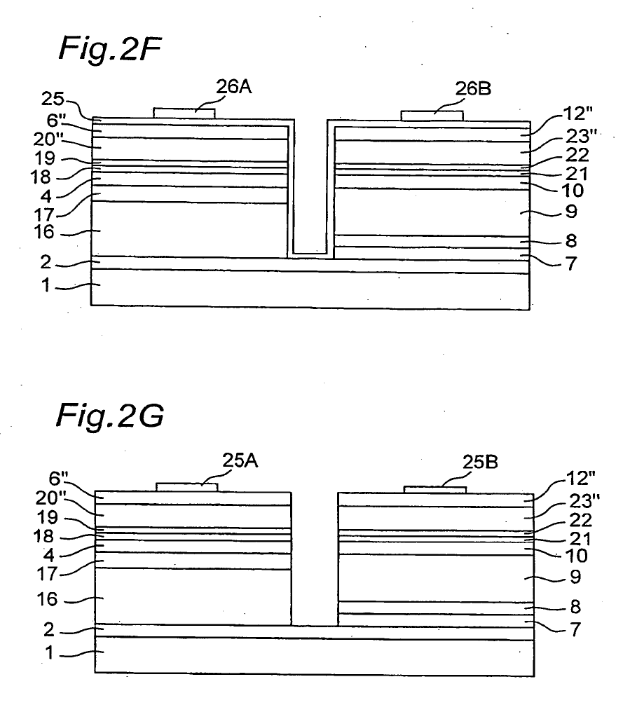

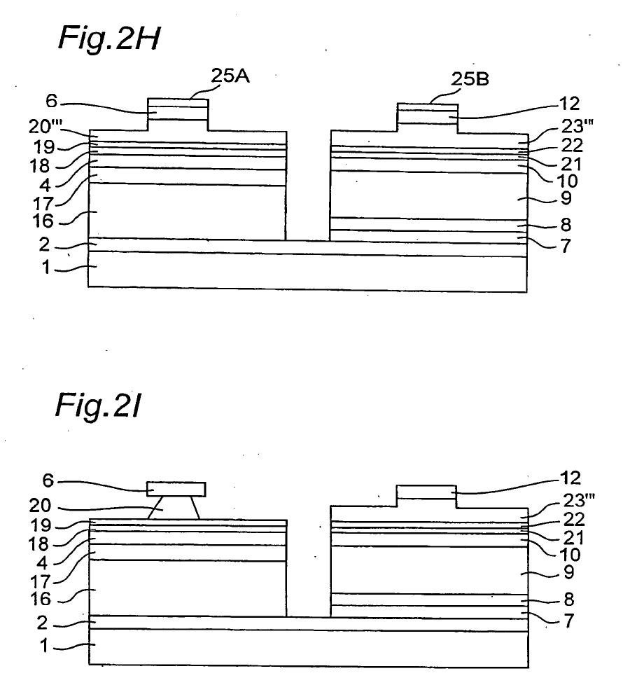

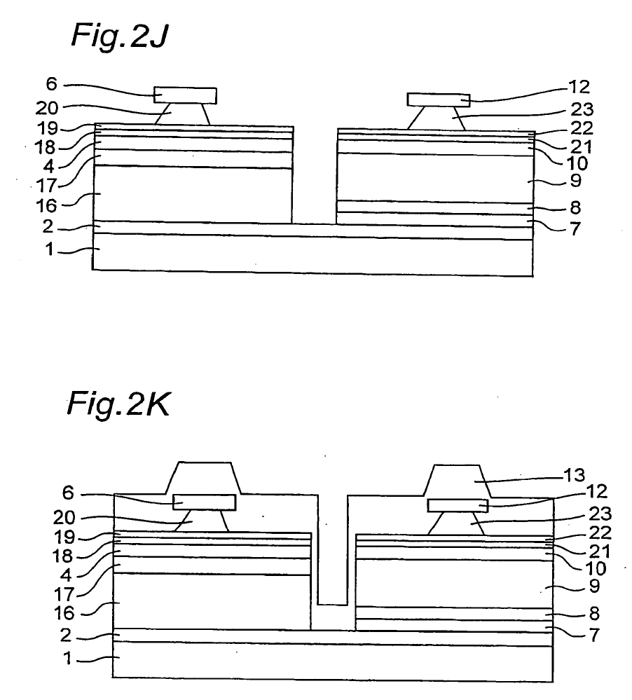

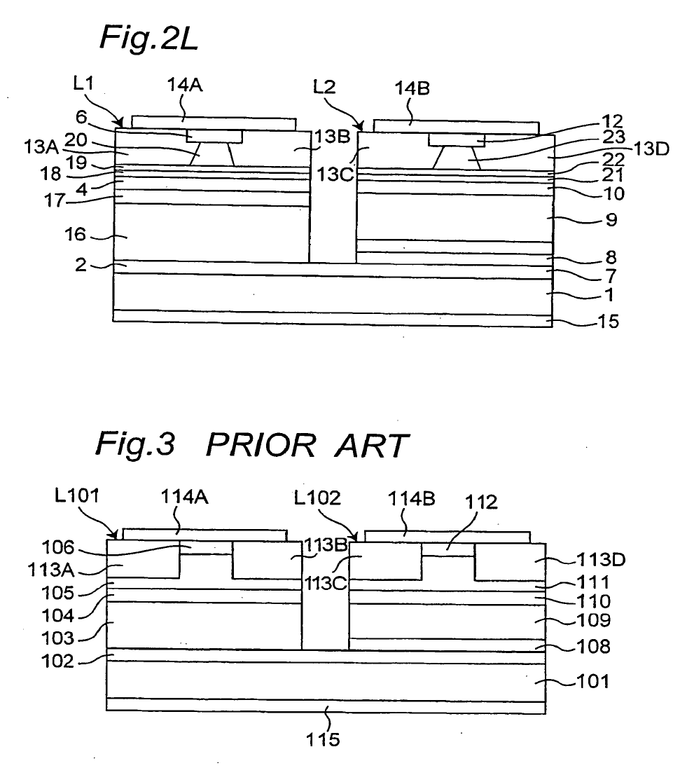

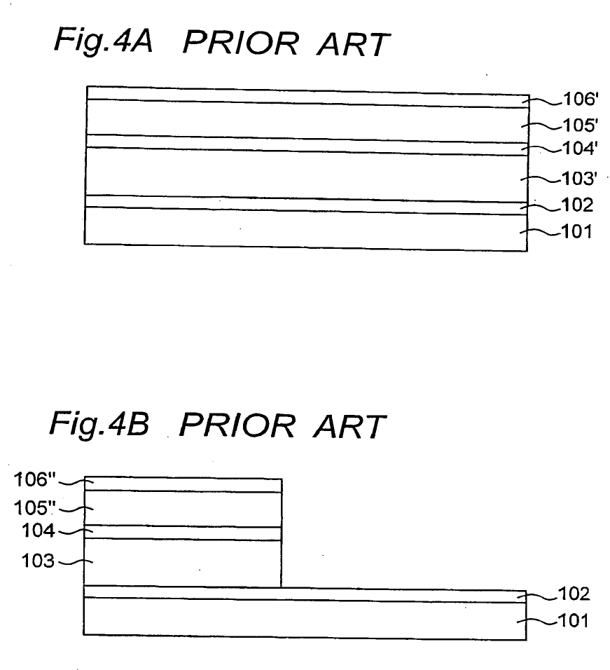

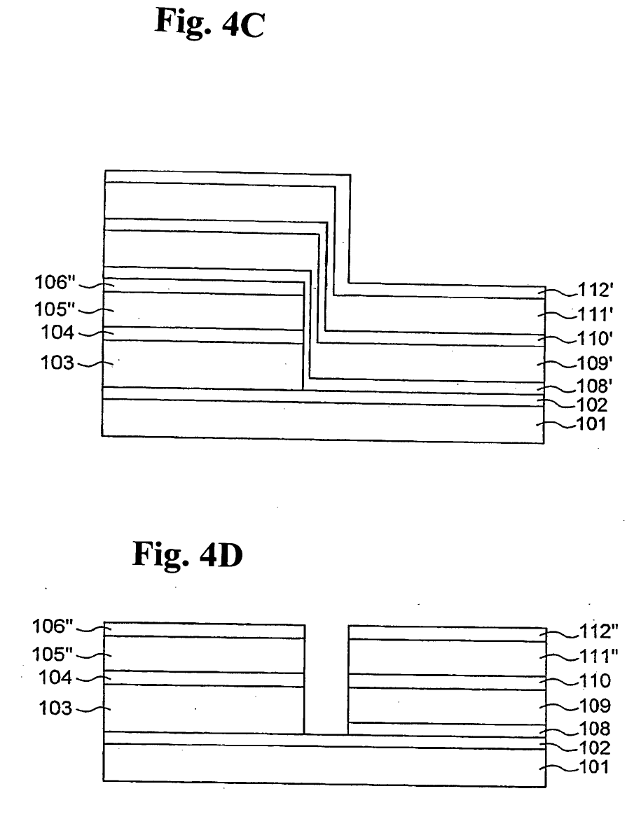

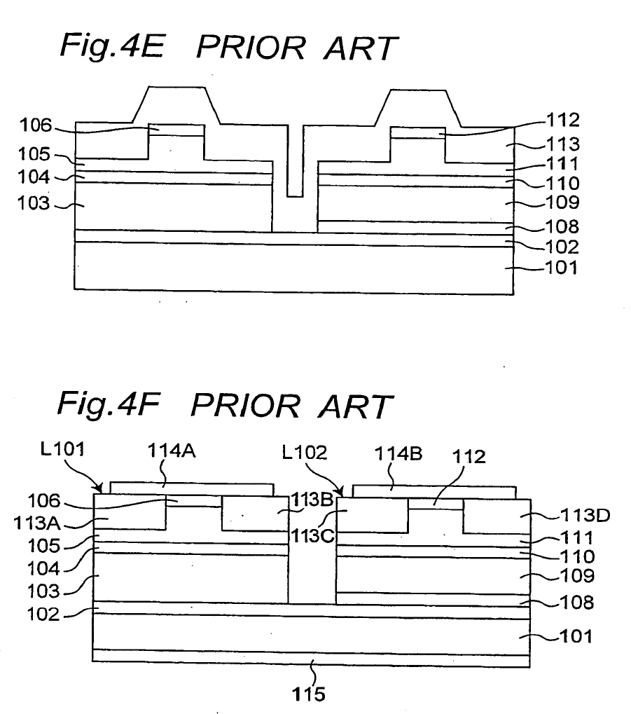

Description is now given of a manufacturing method for the monolithic-type double wavelength laser device with reference to FIGS. 2A to 2L.

First, as shown in FIG. 2A, an Si-doped n-type GaAs buffer layer 2 with a thickness of 0.45 μm, an n-type AlₓGa₁₋ₓAs (X=0.485) first lower cladding layer 16′ with a thickness of 1.5 μm, an n-type AlₓGa₁₋ₓAs (X=0.550) second lower cladding layer 17′ with a thickness of 0.2 μm, a non-doped AlGaAs multiple quantum well active layer 4′ with oscillation wavelength of 780 nm, a p-type AlₓGa₁₋ₓAs (X=0.550) first upper cladding layer 18′ with a thickness of 0.1 μm, p-type GaAs etching stop layer 19′ with a thickness of 28Å, a p-type AlₓGa₁₋ₓAs (X=0.550) second upper cladding layer 20′ with a thickness of 1.0 μm and a p-type GaAs cap layer 6′ with a thickness of 0.8 μm are laminated in sequence on the n-type GaAs substrate 1 by MOCVD (Metal-Organic Chemical Vapor Deposition) method.

Next, a region where the first laser emitting section L1 should be formed is coated with a resist film. Thereafter, the resist film is used as an etching mask to remove parts of the p-type GaAs cap layer 6′ to the n-type AlₓGa₁₋ₓAs (X=0.485) first lower cladding layer 16′ through wet etching. In other words, as shown in FIG. 2B, after the resist film 24 was formed, the resist film 24 is used as an etching mask to perform wet etching so as to form an n-type AlₓGa₁₋ₓAs (X=0.485) first lower cladding layer 16, an n-type AlₓGa₁₋ₓAs (X=0.550) second lower cladding layer 17, an AlGaAs multiple quantum well active layer 4, a p-type AlₓGa₁₋ₓAs (X=0.550) first upper cladding layer 18, a p-type GaAs etching stop layer 19, a p-type AlₓGa₁₋ₓAs (X=0.550) second upper cladding layer 20″ and a p-type GaAs cap layer 6″.

In the wet etching, first, portions from the p-type GaAs cap layer 6′ not coated with the resist film 24 to the almost middle section of the n-type AlₓGa₁₋ₓAs (X=0.485) first lower cladding layer 16′ are removed by use of an etchant capable of removing AlGaAs and GaAs, for example, a sulfuric acid-base etchant of sulfuric acid: hydrolysis: water=1:8:50. Next, by use of HF (hydrogen fluoride), the remaining n-type AlₓGa₁₋ₓAs (X=0.485) first lower cladding layer 16′ is wet-etched.

HF has a small etching rate for GaAs, but it has a large etching rate for AlGaAs. Therefore, in the wet etching using HF, only the n-type AlₓGa₁₋ₓAs (X=0.485) first lower cladding layer 16′ is etched off, and the etching is automatically stopped at the n-type GaAs buffer layer 2.

Next, as shown in FIG. 2C, an n-type GaAs buffer layer 7′ with a thickness of 0.2 μm, an n-type InGaP buffer layer 8′ with a thickness of 0.25 μm, an n-type AlGaInP lower cladding layer 9′ with a thickness of 1.3 μm, a multiple quantum well active layer 10′ with oscillation wavelength of 650 nm, a p-type AlGaInP first upper cladding layer 21′ with a thickness of 0.2 μm, a p-type InGaP etching stop layer 22′ with a thickness of 80Å, a p-type AlGaInP second upper cladding layer 23′ with a thickness of 1.1 μm and a p-type GaAs cap layer 12′ with a thickness of 0.8 μm are laminated in sequence.

Next, after a region where the second laser emitting section L2 should be formed was coated with a resist film, the n-type GaAs buffer layer 7′, the n-type InGaP buffer layer 8′, the n-type AlGaInP lower cladding layer 9′, the multiple quantum well active layer 10′, the p-type AlGaInP first upper cladding layer 21′, the p-type InGaP etching stop layer 22′, the p-type AlGaInP second upper cladding layer 23′ and the p-type GaAs cap layer 12′ are partially wet-etched. By this, as shown in FIG. 2D, an n-type GaAs buffer layer 7, an n-type InGaP buffer layer 8, an n-type AlGaInP lower cladding layer 9, a multiple quantum well active layer 10, a p-type AlGaInP first upper cladding layer 21, a p-type InGaP etching stop layer 22, a p-type AlGaInP second upper cladding layer 23″ and a p-type GaAs cap layer 12″ are obtained.

Next, to form a dry etching mask, as shown in FIG. 2E, an SiO₂ film 25 is formed on the entire surface of the wafer by plasma CVD method.

Next, as shown in FIG. 2F, stripe-shaped resist films 26A, 26B are formed with use of a single photomask (unshown) by the photolithography technique. In this case, the mask accuracy is generally about ±0.3 μm.

Next, after etching was performed by use of buffered hydrofluoric acid, the resist films 26A, 26B are removed to form stripe-shaped SiO₂ films 25A, 25B, as shown in FIG. 2G.

Next, with use of the SiO₂ films 25A, 25B as etching masks, dry etching is performed to form, as shown in FIG. 2H, a p-type GaAs cap layer 6, a p-type AlₓGa₁₋ₓAs (X=0.550) second upper cladding layer 20′″, a p-type GaAs cap layer 12 and a p-type AlGaInP second upper cladding layer 23′″. In this case, the dry etching is performed such that the residual thicknesses of the p-type AlₓGa₁₋ₓAs (X=0.550) second upper cladding layer 20″ and the p-type AlGaInP second upper cladding layer 23′″ are about 0.4 μm.

A ratio of an etching rate A for dry etching of the p-type GaAs cap layer 6″ to the middle of the p-type AlₓGa₁₋ₓAs (X=0.550) second upper cladding layer 20″ to an etching rate B for dry etching of the p-type GaAs cap layer 12″ to the middle of the p-type AlGaInP second upper cladding layer 23″ is 1 to 1.1, i.e., A:B=1:1.1. Also, a ratio of a layer thickness C (=1.8 μm) from the upper face of the p-type GaAs cap layer 6″ to the lower face of the p-type AlₓGa₁₋ₓAs (X=0.550) second cladding layer 20″ to a layer thickness D (=1.98 μm) from the upper face of the p-type GaAs cap layer 12″ to the lower face of the p-type AlGaInP second upper cladding layer 23″ is also 1 to 1.1, i.e., C:D=1:1.1. Thus, because of A:B=C:D, it becomes possible to prevent the p-type GaAs etching stop layer 19 and the p-type InGaP etching stop layer 22 from being dry-etched. That is to say, over etching during the dry etching is prevented from occurring.

Methods for the dry etching include ICP (Inductively Coupled Plasma) dry etching where plasma is used in mixed gas of Cl-base gas and Ar gas.

Next, to remove damages caused by the dry etching, rinse processing was performed with use of a sulfuric acid-base etchant. Thereafter, the p-type AlₓGa₁₋ₓAs (X=0.550) second upper cladding layer 20′″ is wet-etched by HF with 10° C. to form the first ridge stripe. Thus, as shown in FIG. 2I, the first ridge stripe is obtained which is composed of the p-type GaAs cap layer 6 and the p-type AlₓGa₁₋ₓAs (X=0.550) second upper cladding layer 20.

HF described above has a sufficiently small etching rate for GaAs and AlGaInP while having a sufficiently large etching rate for AlGaAs. Therefore, in the wet etching using HF, only the n-type AlₓGa₁₋ₓAs (X−0.550) second cladding layer 20′″ is etched off and the etching is automatically stopped at the n-type GaAs etching stop layer 19. The wet etching in this case does not affect the p-type GaAs cap layer 12 and the p-type AlGaInP second upper cladding layer 23′″. That is, the p-type GaAs cap layer 12 and the p-type AlGaInP second upper cladding layer 23′″ are hardly wet-etched.

The horizontal width of the first ridge stripe as viewed in the drawing can be adjusted by the period of wet etching with HF.

Next, in order to form the second ridge stripe, the p-type AlGaInP second upper cladding layer 23′″ is wet-etched by phosphoric acid with 70° C. As a result, as shown in FIG. 2J, the second ridge stripe is obtained which is composed of the p-type GaAs cap layer 12 and the p-type AlGaInP second upper cladding layer 23.

The phosphoric acid has a small etching rate for GaAs, AlGaAs and InGaP while having a large etching rate for AlGaInP. Therefore, in the wet etching using the phosphoric acid, only the p-type AlGaInP second upper cladding layer 23′″ is etching off and the etching is stopped at the p-type InGaP etching stop layer 22. The wet etching in this case does not affect the p-type GaAs cap layer 6 and the n-type AlₓGa₁₋ₓAs (X=0.550) second cladding layer 20. That is, the p-type GaAs cap layer 6 and the n-type AlₓGa₁₋ₓAs (x=0.550) second cladding layer 20 are hardly wet-etched.

The horizontal width of the second ridge stripe as viewed in the drawing can be adjusted by the period of wet etching with phosphoric acid.

Next, as shown in FIG. 2K, an n-type GaAs current narrowing layer 13 is laminated.

Next, unnecessary part of the n-type GaAs current narrowing layer 13 is removed by etching to form, as shown in FIG. 2L, n-type GaAs current narrowing layers 13A, 13B, 13C and 13D. In other words, the first and second laser emitting sections L1, L2 are obtained. Then, p-side AuZn/Au 14A, 14B are respectively formed on the first and second laser emitting sections L1, L2, and an n-side AuGe/Ni electrode 15 is formed under the n-type GaAs substrate 1.

As described above, the etching masks of only one kind, SiO₂ films 25A, 25B are used so as to form the p-type GaAs cap layer 6, the n-type AlₓGa₁₋ₓAs (X=0.550) second cladding layer 20, the p-type GaAs cap layer 12 and the p-type AlGaInP second upper cladding layer 23. In other words, only SiO₂ films 25A, 25B are used as the etching mask for forming the first and second ridge stripes. Thus, only one photolithography operation is necessary for forming the first and second ridge stripes, thereby allowing the manufacturing step to be simplified.

Moreover, since the SiO₂ films 25A, 25B of only one kind are used for forming the first and second ridge stripes, the position of luminous points of the first and second laser emitting sections L1, L2 may be set with higher precision than the case where the etching masks for forming the first and second ridge stripes are of two kinds.

In this embodiment, a ratio of a layer thickness obtained by adding the layer thickness of the p-type GaAs cap layer 6 and the layer thickness of the p-type AlₓGa₁₋ₓAs is (X=0.550) second cladding layer 20 to a layer thickness obtained by adding the layer thickness of p-type GaAs cap layer 12 and the layer thickness of the p-type AlGaInP second upper cladding layer 23 should be identical to a ratio of an etching rate for dry etching of the p-type GaAs cap layer 6 and the p-type AlₓGa₁₋ₓAs (X=0.550) second cladding layer 20 to an etching rate for dry etching of the p-type. GaAs cap layer 12 and the p-type AlGaInP second upper cladding layer 23.

Further in this embodiment, a ratio of an etching rate A for dry etching of the p-type GaAs cap layer 6″ to the middle of the p-type AlₓGa₁₋ₓAs (X=0.550) second upper cladding layer 20″ to an etching rate B for dry etching of the p-type GaAs cap layer 12″ to the middle of the p-type AlGaInP second upper cladding layer 23″ should be almost identical to a ratio of a layer thickness C from the upper face of the p-type GaAs cap layer 6″ to the lower face of the p-type AlₓGa₁₋ₓAs (X=0.550) second cladding layer 20″ to a layer thickness D from the upper face of the p-type GaAs cap layer 12″ to the lower face of the p-type AlGaInP second upper cladding layer 23″. More particularly, A:B should be almost identical to C:D.

Although the SiO₂ films 25A, 25B have been formed through wet etching with buffered hydrofluoric acid in this embodiment, the SiO₂ films 25A, 25B may be formed through dry etching such as RIE (Reactive Ion Etching).

Further, although the etching rate of ICP dry etching is so set as AlGaAs-base material: AlGaInP-base material=1:1.1 in this embodiment, the ratio of the etching rates changes when the etching method or the etching conditions are changed, and therefore, the layer thickness should be designed according to the changes.

Moreover, the monolithic-type double wavelength laser device may be mounted on drive apparatuses capable of optically recording/reproducing information on both DVDs and CDs.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

1. A semiconductor laser device, comprising:
a substrate;
a first laser emitting section formed on the substrate for emitting a laser light beam with a first wavelength; and
a second laser emitting section formed on the substrate for emitting a laser light beam with a second wavelength different from the first wavelength,
the first laser emitting section having a first conductivity-type lower cladding layer, an active layer, a second conductivity-type first upper cladding layer, an etching stop layer, a second conductivity-type second upper cladding layer and a second conductivity-type cap layer,
the second laser emitting section having a first conductivity-type lower cladding layer, an active layer, a second conductivity-type first upper cladding layer, an etching stop layer, a second conductivity-type second upper cladding layer and a second conductivity-type cap layer, wherein
a first ridge stripe is comprised of the second conductivity-type second upper cladding layer and the second conductivity-type cap layer of the first laser emitting section, while a second ridge stripe is comprised of the second conductivity-type second upper cladding layer and the second conductivity-type cap layer of the second laser emitting section, and wherein
a ratio of a layer thickness obtained by adding a layer thickness of the second conductivity-type cap layer of the first laser emitting section and a layer thickness of the second conductivity-type second upper cladding layer of the first laser emitting section to a layer thickness obtained by adding a layer thickness of the second conductivity-type cap layer of the second laser emitting section and a layer thickness of the second conductivity-type second upper cladding layer of the second laser emitting section is almost identical to a ratio of an etching rate for etching the second conductivity-type second upper cladding layer of the first laser emitting section and the second conductivity-type cap layer of the first laser emitting section to an etching rate for etching the second conductivity-type second upper cladding layer of the second laser emitting section and the second conductivity-type cap layer of the second laser emitting section.

2. The semiconductor laser device as defined in claim 1, wherein
the first laser emitting section contains an AlGaAs-base material while the second laser emitting section contains an AlGaInP-base material.

3. The semiconductor laser device as defined in claim 1, wherein
the first ridge stripe extends along a resonator direction of the laser light beam with the first wavelength, while the second ridge stripe extends along a resonator of the laser light beam with the second wavelength.

4. A manufacturing method for a semiconductor laser device having a substrate; a first laser emitting section formed on the substrate for emitting a laser light beam with a first wavelength; and a second laser emitting section formed on the substrate for emitting a laser light beam with a second wavelength different from the first wavelength,
the first laser emitting section having a first conductivity-type lower cladding layer, an active layer, a second conductivity-type first upper cladding layer, an etching stop layer, a second conductivity-type second upper cladding layer and a second conductivity-type cap layer,
the second laser emitting section having a first conductivity-type lower cladding layer, an active layer, a second conductivity-type first upper cladding layer, an etching stop layer, a second conductivity-type second upper cladding layer and a second conductivity-type cap layer, wherein
a first ridge stripe is comprised of the second conductivity-type second upper cladding layer of the first laser emitting section and the second conductivity-type cap layer of the first laser emitting section, while a second ridge stripe is comprised of the second conductivity-type second upper cladding layer of the second laser emitting section and the second conductivity-type cap layer of the second laser emitting section,
the manufacturing method comprising the steps of:
forming a first semiconductor layer to be the second conductivity-type second upper cladding layer of the first laser emitting section on the substrate;
forming a second semiconductor layer to be the second conductivity-type cap layer of the first laser emitting section on the first semiconductor layer;
forming a third semiconductor layer to be the second conductivity-type second upper cladding layer of the second laser emitting section on the substrate;
forming a fourth semiconductor layer to be the second conductivity-type cap layer of the second laser emitting section on the third semiconductor layer;
forming an etching mask on the second semiconductor layer and the fourth semiconductor layer in one photolithography operation; and
performing etching with use of the etching mask so as to remove parts of the first semiconductor layer, the second semiconductor layer, the third semiconductor layer and the fourth semiconductor layer, wherein
a ratio of a layer thickness obtained by adding a layer thickness of the second semiconductor layer and a layer thickness of the first semiconductor layer to a layer thickness obtained by adding a layer thickness of the fourth semiconductor layer and a layer thickness of the third semiconductor layer is almost identical to a ratio of an etching rate for etching from the second semiconductor layer toward the substrate to the first semiconductor layer to an etching rate for etching from the fourth semiconductor layer toward the substrate to the third semiconductor layer.

5. The manufacturing method for the semiconductor laser device as defined in claim 4, wherein
the etching mask is formed from one photomask.

6. The manufacturing method for the semiconductor laser device as defined in claim 4, wherein
etching with use of the etching mask is performed in combination of dry etching and wet etching performed after the dry etching.

7. The manufacturing method for the semiconductor laser device as defined in claim 6, wherein
in the wet etching, an etchant allowing selective etching of the first semiconductor layer is used and an etchant allowing selective etching of the third semiconductor layer is used.
